(19) United States
(12) Patent Application Publication
(10) Pub. No.: US 2026/0215192 A1
(43) Pub. Date: Jul. 23, 2026

(54) METHOD FOR PRODUCING SEMICONDUCTOR CHIPS

(71) Applicant: Resonac Corporation, Minato-ku, Tokyo (JP)

(72) Inventors: Tatsuya MAKINO, Tokyo (JP); Toshiaki SHIRASAKA, Tokyo (JP)

(21) Appl. No.: 19/135,101

(22) PCT Filed: Dec. 7, 2023
(86) PCT No.: PCT/JP2023/043899

§ 371 Date: Jun. 3, 2025

(30) Foreign Application Priority Data
Dec. 9, 2022 (JP) 2022-197199

(51) Int. Cl. H10P 52/40; H10P 58/00; H10P 72/70

(52) U.S. Cl. CPC H10P 52/402; H10P 58/00; H10P 72/7402; H10P 72/7416; H10P 72/7422; H10P 72/7442

(57) ABSTRACT

A method for manufacturing a semiconductor chip, the method including: preparing a surface-protected laminated body having a semiconductor wafer having a circuit surface and a back surface, a protective layer, and a back grinding tape; grinding the semiconductor wafer from the back surface side, thereby thinning the semiconductor wafer; fixing the surface-protected laminated body onto a dicing tape; peeling the back grinding tape from the surface-protected laminated body; dividing he semiconductor wafer on the dicing tape together with the protective layer, thereby forming a semiconductor chip; and removing the protective layer attached to the semiconductor chip.

### TECHNICAL FIELD

The present disclosure relates to a method for manufacturing a semiconductor chip from a semiconductor wafer.

### BACKGROUND ART

In dicing a semiconductor wafer for manufacturing semiconductor chips, in order to avoid the adhesion of fine debris resulting from dicing and to avoid damage to the semiconductor wafer, it has been considered to provide a protective layer that temporarily protects the surface of the semiconductor wafer during dicing (for example, Patent Literatures 1 and 2).

### CITATION LIST

### Patent Literature

Patent Literature 1: Japanese Unexamined Patent Publication No. 2014-172932
Patent Literature 2: Japanese Unexamined Patent Publication No. 2018-129365

### SUMMARY OF INVENTION

### Technical Problem

A protective layer that protects the surface of a semiconductor wafer may be formed by a method including heating. It has been made clear that due to the effect of heating for forming the protective layer, a dicing sheet to which the semiconductor wafer is fixed for dicing undergoes thermal shrinkage, which may affect the stability of the process.

An aspect of the present disclosure relates to suppressing the effect of thermal shrinkage of a dicing tape in a case where semiconductor chips are manufactured by a method including dividing a semiconductor wafer protected by a protective layer on a dicing tape.

### Solution to Problem

The present disclosure includes at least the following items.
[1] A method for manufacturing a semiconductor chip, the method including:
preparing a surface-protected laminated body having a semiconductor wafer having a circuit surface and a back surface on an opposite side thereof, a protective layer, and a back grinding tape, the protective layer being provided so as to cover the circuit surface, and the back grinding tape being laminated on a surface of the protective layer on an opposite side of the semiconductor wafer;
grinding the semiconductor wafer included in the surface-protected laminated body from the back surface side, thereby thinning the semiconductor wafer;
fixing the surface-protected laminated body included in the thinned semiconductor wafer onto a dicing tape in a direction in which the semiconductor wafer is located on the dicing tape side;
peeling the back grinding tape from the surface-protected laminated body having the thinned semiconductor wafer;
after the back grinding tape is peeled from the surface-protected laminated body, dividing the semiconductor wafer on the dicing tape together with the protective layer, thereby forming a semiconductor chip to which the divided protective layer is attached; and
removing the protective layer attached to the semiconductor chip.
[2] The method according to [1], wherein the back grinding tape is a UV-curable back grinding tape, and the method further includes irradiating the back grinding tape with ultraviolet radiation, after the semiconductor wafer is thinned and before the back grinding tape is peeled from the surface-protected laminated body.
[3] The method according to [1] or [2], wherein the surface-protected laminated body is prepared by a method including:
forming a film of a coating composition for forming a protective layer on the circuit surface of the semiconductor wafer; and
heating the film to 50° C. or higher, and thereby forming the protective layer.
[4] The method according to any one of [1] to [3], wherein the protective layer has a thickness of 0.3 to 20.0 μm.
[5] The method according to any one of [1] to [4], wherein the dicing tape has a base material film containing a polyolefin, a polyvinyl chloride, or an ethylene-vinyl acetate copolymer, and an adhesive layer provided on the base material film.
[6] The method according to any one of [1] to [5], wherein the protective layer contains an alkali water-soluble organic resin, and the protective layer attached to the semiconductor chip is removed by an alkaline aqueous solution.
[7] The method according to [6], wherein the alkali water-soluble organic resin includes at least one selected from the group consisting of an acrylic resin having a carboxy group which may form a salt, a urethane compound having a carboxy group which may form a salt, a copolymer containing an acid anhydride as a monomer unit, and a polysaccharide.

### Advantageous Effects of Invention

In a case where a semiconductor chip is manufactured by a method including dividing a semiconductor wafer protected by a protective layer on a dicing tape, the effect of thermal shrinkage of the dicing tape can be suppressed. A dicing tape that is highly flexible but is not very highly heat-resistant can be selected. When a highly flexible dicing tape is used, a semiconductor chip obtained after dicing can be picked up more easily.

### BRIEF DESCRIPTION OF DRAWINGS

FIG. 1 is a process diagram illustrating an example of a method for manufacturing a semiconductor chip.

FIG. 2 is a process diagram illustrating an example of the method for manufacturing a semiconductor chip.

FIG. 3 is a process diagram illustrating an example of the method for manufacturing a semiconductor chip.

### DESCRIPTION OF EMBODIMENTS

The present invention is not limited to the following example.

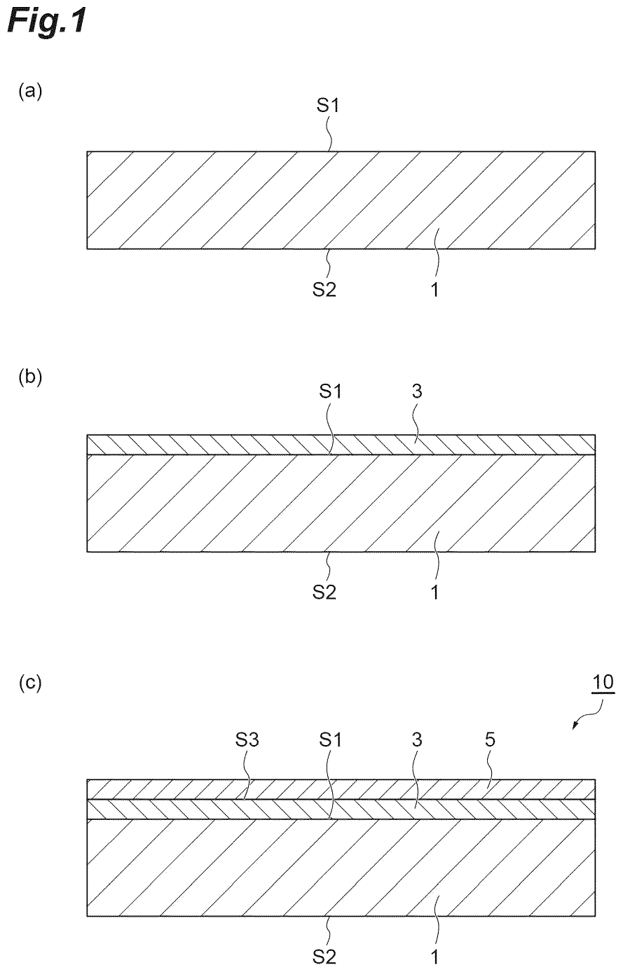

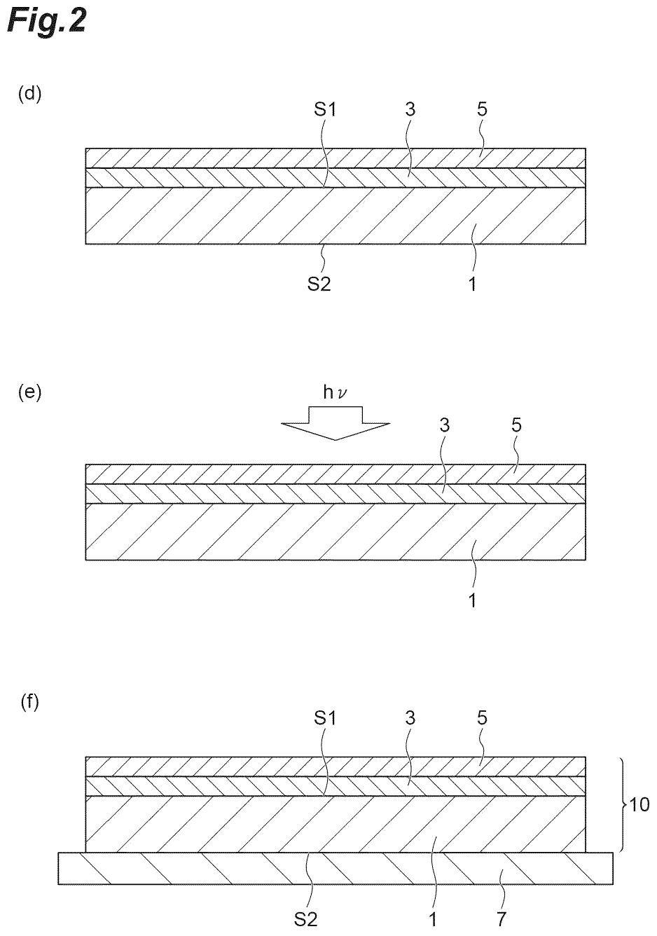

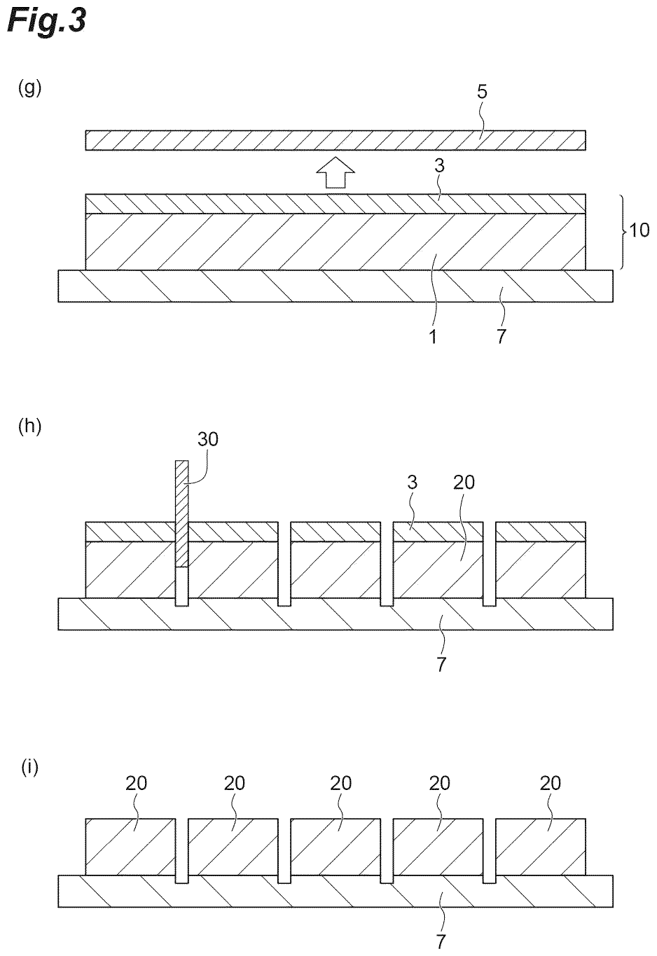

FIG. 1, FIG. 2, and FIG. 3 are process diagrams illustrating an example of the method for manufacturing a semiconductor chip. The method shown in FIGS. 1 to 3 includes: preparing a surface-protected laminated body 10 that has a semiconductor wafer 1 having a circuit surface S1 and a back surface S2 on the opposite side thereof, a protective layer 3, and a back grinding tape 5 ((a), (b), and (c) in FIG. 1); grinding the semiconductor wafer 1 included in the surface-protected laminated body 10 from the back surface S2 side, thereby thinning the semiconductor wafer 1 ((d) in FIG. 2); fixing the surface-protected laminated body 10 having the thinned semiconductor wafer 1 onto a dicing tape 7 in a direction in which the semiconductor wafer 1 is located on the dicing tape 7 side ((f) in FIG. 2); peeling the back grinding tape 5 from the surface-protected laminated body 10 having the thinned semiconductor wafer 1 ((g) in FIG. 3.); dividing the semiconductor wafer 1 on the dicing tape 7 together with the protective layer 3, thereby forming a semiconductor chip 20 to which the divided protective layer 3 is attached ((h) in FIG. 3); and removing the protective layer 3 attached to the semiconductor chip 20 ((i) in FIG. 3). A plurality of semiconductor chips 20 are formed by dicing, by which the semiconductor wafer 1 is divided.

The semiconductor wafer 1 can be, for example, a silicon wafer. An integrated circuit is formed on a surface layer part on the circuit surface S1 side of the semiconductor wafer 1. The circuit surface S1 may include a surface of a thermal oxide film. The thickness of the semiconductor wafer 1 before being thinned may be, for example, 400 to 900 μm.

The protective layer 3 is provided so as to cover the circuit surface S1. The protective layer 3 may cover the entirety of the circuit surface S1. The protective layer 3 may contain an alkali water-soluble organic resin. The protective layer 3 is formed by, for example, a method including forming a film of a coating composition for forming a protective layer containing an organic resin and a solvent on the circuit surface S1, and heating the film. At this time point, since the semiconductor wafer 1 is not fixed onto the dicing tape 7, the protective layer 3 can be formed without subjecting the dicing tape 7 to a thermal history. In a case where the coating composition contains a solvent, the solvent is removed by heating the film. The heating temperature for forming the protective layer 3 is suitably set such that the protective layer 3 is appropriately formed; however, the heating temperature may be, for example, 50° C. or higher, 60° C. or higher, or 70° C. or higher. The upper limit of the heating temperature is not particularly limited but is usually about 150° C. The details of the organic resin constituting the protective layer 3 and the coating composition for forming the protective layer 3 will be described below. It is also acceptable to prepare in advance a protective layer 3 formed on a base material film, and laminate the protective layer 3 on the circuit surface S1.

From the viewpoint of appropriate protection of the semiconductor wafer, the thickness of the protective layer 3 may be 0.3 μm or more, 0.5 μm or more, or 0.8 μm or more. The thickness of the protective layer 3 depends on the uneven structure of the semiconductor wafer surface; however, from the viewpoint of shortening the time required for the removal, the thickness may be 20.0 μm or less, 15.0 μm or less, or 10.0 μm or less. For example, the thickness of the protective layer may be 0.3 to 20.0 μm, 0.5 to 15.0 μm, or 0.8 to 10.0 μm.

After the protective layer 3 is formed, the back grinding tape 5 is laminated on a surface S3 of the protective layer 3 on the opposite side of the semiconductor wafer 1. The back grinding tape 5 may be, for example, a UV-curable back grinding tape whose adhesive strength decreases when irradiated with ultraviolet radiation. The surface-protected laminated body 10 may also be prepared by a method including preparing in advance a laminated film which has a support film, a back grinding tape 5, and a protective layer 3 and in which these are laminated in this order, and laminating the laminated film on the semiconductor wafer 1 in a direction in which the protective layer 3 is located on the semiconductor wafer 1 side. In a state of being fixed by the back grinding tape 5, the semiconductor wafer 1 is ground from the back surface S2 side. The thickness of the semiconductor wafer 1 is reduced by grinding. The grinding method can be, for example, a conventional back grinding method such as chemical mechanical polishing. The thickness of the thinned semiconductor wafer 1 may be, for example, 30 to 200 μm.

In a case where the back grinding tape 5 is of a UV-curable type, before the back grinding tape 5 is peeled from the surface-protected laminated body 10, the back grinding tape 5 is irradiated with ultraviolet radiation hv, as shown in (e) in FIG. 2. A UV-curable back grinding tape can be particularly easily peeled from the protective layer 3.

Subsequently, in the case of the examples in FIG. 2 and FIG. 3, the surface-protected laminated body 10 is fixed onto the dicing tape 7, and then the back grinding tape 5 is peeled from the surface-protected laminated body 10. Alternatively, after the back grinding tape 5 is peeled from the surface-protected laminated body 10, the surface-protected laminated body 10 composed of the semiconductor wafer 1 and the protective layer 3 may be fixed onto the dicing tape 7.

The dicing tape 7 can be selected from those conventionally used for dicing of a semiconductor wafer. The dicing tape 7 may have a base material film and an adhesive layer provided on the base material film. In that case, usually, the surface-protected laminated body 10 is attached to the adhesive layer. When the base material film has high flexibility, semiconductor chips 20 are likely to be satisfactorily picked up after dicing. From this viewpoint, the base material film may be, for example, a resin film containing a polyolefin, a polyvinyl chloride, or an ethylene-vinyl acetate copolymer. A base material film having high flexibility tends to undergo thermal shrinkage relatively easily; however, in the method according to the present disclosure, since the base material film can avoid being subjected to a thermal history at high temperatures, a base material film having high flexibility can also be selected.

The thickness of the dicing tape is not particularly limited; however, the thickness may be, for example, 50 to 300 μm. In a case where the dicing tape 7 has a base material film and an adhesive layer, for example, the thickness of the base material film may be 30 to 275 μm, and the thickness of the adhesive layer may be 1 to 50 μm.

After the back grinding tape 5 is peeled from the surface-protected laminated body 10, the semiconductor wafer 1 on the dicing tape 7 is divided together with the protective layer 3 by dicing. As a result, a plurality of semiconductor chips 20 to which the divided protective layer 3 is attached are formed on the dicing tape 7. Dicing is carried out using, for example, a dicing saw 30.

After the dicing, the protective layer 3 attached to each semiconductor chip 20 is removed. The protective layer 3 is removed by, for example, contacting with a cleaning liquid. The time for contact between the protective layer 3 and the cleaning liquid for the removal of the protective layer 3 may be, for example, 5 to 300 seconds. The temperature of the cleaning liquid may be, for example, 5° C. to 30° C. In a case where the protective layer 3 contains an alkali water-soluble organic resin, an alkaline aqueous solution can be used as the cleaning liquid. The alkaline aqueous solution as the cleaning liquid may be, for example, an aqueous solution of ammonia or an aqueous solution of tetramethylammonium hydroxide (TMAH). The concentration of the aqueous solution of ammonia may be, for example, 0.01% to 5% by mass, 0.1% to 3.0% by mass, or 0.5% to 2.0% by mass, based on the mass of the aqueous solution of ammonia. The concentration of the aqueous solution of TMAH may be, for example, 0.1% to 10% by mass, 0.5% to 5% by mass or less, or 1.0% to 5.0% by mass, based on the mass of the aqueous solution of TMAH.

After the protective layer 3 is removed, the semiconductor chip 20 is picked up from the dicing tape 7. The semiconductor chip 20 thus picked up is mounted on various members according to the purpose, such as a wiring substrate or another semiconductor chip.

The organic resin constituting the protective layer 3 may also be an alkali water-soluble organic resin. When the protective layer 3 contains an organic resin that is water-insoluble and alkali water-soluble, the protective layer 3 is particularly likely to have resistance to dicing using water. Specifically, the protective layer 3 may contain at least one alkali water-soluble organic resin selected from the group consisting of an acrylic resin having a carboxy group which may form a salt, a urethane compound having a carboxy group which may form a salt, a copolymer containing an acid anhydride as a monomer unit, and a polysaccharide.

The acrylic resin having a carboxy group can be a copolymer having a monomer unit derived from a monomer having a carboxy group, and a monomer unit derived from a (meth)acrylic acid alkyl ester which does not have a carboxyl group. In the present specification, the term “(meth)acryl” means methacryl or acryl. Some or all of the carboxy groups in the acrylic resin may form a salt such as a metal salt or an ammonium salt.

Examples of the monomer having a carboxy group include (meth)acrylic acid, α-bromo(meth)acrylic acid, α-chloro(meth)acrylic acid, β-furyl(meth)acrylic acid, β-styryl(meth)acrylic acid, fumaric acid, cinnamic acid, α-cyanocinnamic acid, itaconic acid, crotonic acid, and propiolic acid. From the viewpoint of improving the solubility of the protective layer 3 in an alkali aqueous solution, the monomer having a carboxy group may be (meth)acrylic acid.

From the viewpoint of a balance between the water resistance during dicing and the solubility in an alkali aqueous solution, the proportion of a monomer unit derived from a carboxy group may be 5% to 25% by mass, 8% to 20% by mass, or 10% to 15% by mass, based on the total mass of the monomer units constituting the acrylic resin.

Examples of the (meth)acrylic acid alkyl ester include methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, nonyl (meth)acrylate, decyl (meth)acrylate, undecyl (meth)acrylate, dodecyl (meth)acrylate (lauryl (meth)acrylate), tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl (meth)acrylate. The acrylic resin may contain one or more monomers selected from these as monomer units.

From the viewpoint of improving water resistance during dicing, the proportion of a monomer unit derived from a (meth)acrylic acid alkyl ester may be 40% by mass or more, 50% by mass or more, or 55% by mass or more, based on the total mass of the monomer units constituting the acrylic resin. From the viewpoint of improving solubility in an alkali aqueous solution, the proportion of the monomer unit derived from a (meth)acrylic acid alkyl ester may be 90% by mass or less, 88% by mass or less, or 85% by mass or less, based on the total mass of the monomer units constituting the acrylic resin.

From the viewpoint of improving water resistance during dicing, the acrylic resin having a carboxy group may further have a monomer unit derived from styrene or a styrene derivative. Examples of the styrene derivative include vinyltoluene, «-methylstyrene, p-methylstyrene, and p-ethylstyrene.

From the viewpoint of improving solubility in an alkali aqueous solution, the acrylic resin having a carboxy group may further have a monomer unit derived from a monomer having a hydroxyl group. Examples of the monomer having a hydroxyl group include 2-hydroxyethyl (meth)acrylate, 2-hydroxypropyl (meth)acrylate, 3-hydroxypropyl (meth)acrylate, 4-hydroxybutyl (meth)acrylate, 2-hydroxybutyl (meth)acrylate, and glycerol mono(meth)acrylate.

The acrylic resin having a carboxy group may further have a monomer unit derived from a monomer other than those listed above as examples. Examples thereof include benzyl (meth)acrylate or a derivative thereof, acrylonitrile, tetrahydrofurfuryl (meth)acrylate, glycidyl (meth)acrylate, 2,2,2-trifluoroethyl (meth)acrylate, and 2,2,3,3-tetrafluoropropyl (meth)acrylate.

From the viewpoint of improving solubility in an alkali aqueous solution, the acid value of the acrylic resin having a carboxy group may be 50 mg KOH/g or more, 60 mg KOH/g or more, or 70 mg KOH/g or more. From the viewpoint of improving water resistance during dicing, the acid value of the acrylic resin having a carboxy group may be 150 mg KOH/g or less, 140 mg KOH/g or less, or 130 mg KOH/g or less.

The urethane compound having a carboxy group can be, for example, a compound having a linear polyurethane chain having a plurality of urethane groups, and a constituent unit having a carboxy group, which is bonded to the polyurethane chain. Some or all of the carboxy groups in the urethane compound may form a salt such as a metal salt or an ammonium salt. The constituent unit having a carboxy group or a salt thereof may also be, for example, a divalent group represented by the following Formula (1) or (1)′:

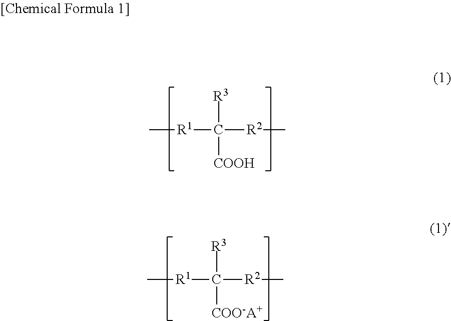

In Formulas (1) and (1)′, R¹ and R² each independently represent an alkylene group having 1 to 10 carbon atoms, R³ represents an alkyl group having 1 to 10 carbon atoms, and A⁺ represents a counter cation.

The ammonium salt formed by a carboxy group in an acrylic resin or a urethan compound may be, for example, a salt formed by a carboxylate anion (—COO⁻) formed from a carboxy group and an ammonium cation represented by the following Formula (2):

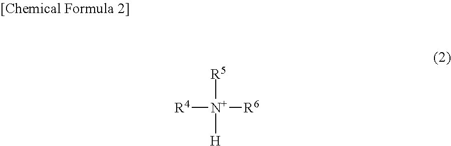

In Formula (2), R⁴, R⁵, and R⁶ each independently represent a hydrogen atom, an aryl group, or an alkyl having 1 to 10 carbon atoms. A⁺ in Formula (1)′ may be an ammonium cation represented by Formula (2).

The copolymer containing an acid anhydride as a monomer unit may be a copolymer containing an acid anhydride and a hydrophobic monomer as monomer units.

The acid anhydride may be, for example, at least one selected from maleic anhydride, itaconic anhydride, acetic anhydride, propionic anhydride, oxalic anhydride, succinic anhydride, phthalic anhydride, and benzoic anhydride, or may be maleic anhydride.

The proportion of the monomer unit derived from an acid anhydride may be 30 mol % or more, 40 mol % or more, or 50 mol % or more, or may be 95 mol % or less, 90 mol % or less, or 85 mol % or less, based on the total amount of the monomer units constituting the copolymer.

The hydrophobic monomer may be, for example, at least one selected from styrene, a (meth)acrylic acid ester, «-methylstyrene, vinyl acetate, and vinyl chloride, or may be at least one selected from styrene, an acrylic acid ester, and a methacrylic acid ester. Examples of the (meth)acrylic acid ester include a (meth)acrylic acid methyl ester, a (meth)acrylic acid ethyl ester, a (meth)acrylic acid propyl ester, a (meth)acrylic acid isopropyl ester, a (meth)acrylic acid sec-butyl ester, a (meth)acrylic acid tert-butyl ester, a (meth)acrylic acid isobutyl ester, a (meth)acrylic acid allyl ester, a (meth)acrylic acid phenyl ester, a (meth)acrylic acid benzyl ester, a (meth)acrylic acid lauryl ester, and a (meth)acrylic acid stearyl ester.

The proportion of the monomer unit derived from a hydrophobic monomer may be 5 mol % or more, 10 mol % or more, or 15 mol % or more, and may be 70 mol % or less, 60 mol % or less, or 50 mol % or less, based on the total amount of the monomer units constituting the copolymer.

The polysaccharide may be, for example, a modified cellulose having a sugar chain derived from cellulose and containing a hexose, and an organic group which has been introduced by substituting a hydroxyl group of the hexose. The organic group may be, for example, at least one selected from —R, —O—R, —NH—R, —C(═O)—R, —C(═O)—R—OH, —R—O—R, —R—NH—R, —R—COOH, —C(═O)—R—COOH, —C(═O)—R—OH, —C(═O)—R—COOH, and —NH₂. R shown herein represents a monovalent or divalent hydrocarbon group. A plurality of R's in the same molecule may be identical or different.

From the viewpoint of stabilized formation of the protective layer 3, the weight average molecular weight of the organic resin (for example, an acrylic resin) may be 10000 or more, 15000 or more, 20000 or more, 30000 or more, or 40000 or more. From the viewpoint of easy removal of the protective layer 3, the weight average molecular weight of the organic resin (for example, acrylic resin) may be 100000 or less, 90000 or less, 80000 or less, 70000 or less, or 60000 or less. The weight average molecular weight of the organic resin may be 10000 or more and 100000 or less. The weight average molecular weight as used herein is a value measured by a gel permeation chromatography (GPC) method and calculated relatively based on a calibration curve of polystyrene standards.

The content of the organic resin in the protective layer 3 may be 60% by mass or more, 65% by mass or more, 70% by mass or more, 75% by mass or more, 80% by mass or more, 85% by mass or more, 90% by mass or more, or 95% by mass or more, and may be 100% by mass or less, based on the mass of the protective layer 3.

The protective layer 3 may further contain components other than the organic resin. The other components can include, for example, a leveling agent, a coupling agent, or a combination thereof.

A leveling agent is a component that suppresses striations (cissing, unevenness, and the like) when a coating composition containing an organic resin is applied on a semiconductor wafer. Examples of the leveling agent include polyoxyethylene lauryl ether, polyoxyethylene stearyl ether, polyoxyethylene oleyl ether, and polyoxyethylene octyl phenol ether. Examples of commercially available products of the leveling agent include MEGAFAC F171, F173, R-08 (manufactured by DIC Corporation, trade names), FLUORAD FC430, FC431 (manufactured by Sumitomo 3M, Ltd., trade names), and organosiloxane polymers KP341, KBM303, KBM403, and KBM803 (manufactured by Shin-Etsu Chemical Co., Ltd., trade names).

In a case where the protective layer 3 contains a leveling agent, the content thereof may be 5 parts by mass or less, 3 parts by mass or less, or 2 parts by mass or less, and may be 0.01 parts by mass or more, 0.03 parts by mass or more, or 0.05 parts by mass or more, with respect to 100 parts by mass of the organic resin. The content of the leveling agent may also be 0.01 parts by mass or more and 5 parts by mass or less with respect to 100 parts by mass of the organic resin.

The coupling agent can further suppress peeling of the protective layer during dicing. The coupling agent may contain, for example, an organic silane compound, an aluminum chelate compound, or a combination thereof.

Examples of the organic silane compound include vinyltriethoxysilane, γ-glycidoxypropyltriethoxysilane, Y-methacryloxypropyltrimethoxysilane, urea propyltriethoxysilane, methylphenylsilanediol, ethylphenylsilanediol, n-propylphenylsilanediol, n-butylphenylsilanediol, isopropylphenylsilanediol, isobutylphenylsilanediol, tert-butylphenylsilanediol, diphenylsilanediol, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl-n-ethylisopropylphenylsilanol, n-propylphenylsilanol, butylethylphenylsilanol, isobutylethylphenylsilanol, tert-butylethylphenylsilanol, methyldiphenylsilanol, ethyldiphenylsilanol, n-propyldiphenylsilanol, isopropyldiphenylsilanol, n-butyldiphenylsilanol, isobutyldiphenylsilanol, tert-butyldiphenylsilanol, phenylsilanetriol, 1,4-bis(trihydroxysilyl)benzene, 1,4-bis(methyldihydroxysilyl)benzene, 1,4-bis(ethyldihydroxysilyl)benzene, 1,4-bis(propyldihydroxysilyl)benzene, 1,4-bis(butyldihydroxysilyl)benzene, 1,4-bis(dimethylhydroxysilyl)benzene, 1,4-bis(diethylhydroxysilyl)benzene, 1,4-bis(dipropylhydroxysilyl)benzene, and 1,4-bis(dibutylhydroxysilyl)benzene.

In a case where the protective layer 3 contains a coupling agent, the content thereof may be 10 parts by mass or less, 8 parts by mass or less, or 5 parts by mass or less, and may be 0.1 parts by mass or more, 0.3 parts by mass or more, or 0.5 parts by mass or more, with respect to 100 parts by mass of the organic resin. The content of the coupling agent may be 0.1 parts by mass or more and 10 parts by mass or less with respect to 100 parts by mass of the organic resin.

The coating composition for forming the protective layer 3 may 10 contain an organic resin listed above as an example and a solvent capable of dissolving the organic resin.

In a case where the organic resin is an acrylic resin having a carboxy group, the solvent may contain, for example, a glycol ether, an aliphatic carboxylic acid ester, or a combination thereof.

Examples of the glycol ether include ethylene glycol monomethyl ether acetate, ethylene glycol monoethyl ether acetate, propylene glycol monomethyl ether acetate, propylene glycol monoethyl ether acetate, propylene glycol monopropyl ether acetate, propylene glycol monobutyl ether acetate, propylene glycol monomethyl ether, propylene glycol monoethyl ether, propylene glycol monopropyl ether, propylene glycol 20 monobutyl ether, propylene glycol dimethyl ether, propylene glycol diethyl ether, propylene glycol dipropyl ether, and propylene glycol dibutyl ether.

Examples of the aliphatic carboxylic acid ester include, for example, methyl lactate, ethyl lactate, n-propyl lactate, isopropyl lactate, ethyl acetate, n-propyl acetate, isopropyl acetate, n-butyl acetate, isobutyl acetate, n-amyl acetate, isoamyl acetate, isopropyl propionate, n-butyl propionate, and isobutyl propionate.

In a case where the organic resin is a urethane compound having a carboxy group, the solvent may be, for example, an alcohol such as isopropyl alcohol or tetrahydrofurfuryl alcohol.

In a case where the organic resin is a copolymer containing an acid anhydride as a monomer unit, the solvent may be ammonia or an alkaline amine-based organic solvent. Examples of the amine-based organic solvent include an aliphatic amine, an aromatic amine, a heterocyclic amine, and an organic ammonium (for example, quaternary ammonium hydroxide).

In a case where the organic resin is a polysaccharide, the solvent may include, for example, at least one selected from a ketone, an alcohol, dimethylformamide, dimethyl sulfoxide, and N-methyl-2-pyrrolidone.

Examples of the ketone include cyclohexanone and methyl ethyl ketone. Examples of the alcohol include propylene glycol monomethyl ether, isopropyl alcohol, and benzyl alcohol.

The content of the organic resin in the coating composition may be, for example, 5% to 30% by mass, 8% to 25% by mass, or 10% to 20% by mass, based on the mass of the coating composition.

### EXAMPLES

The present invention is not limited to the following Examples.

### 1. Coating Composition

In a flask equipped with a stirrer, a cooler, a gas inlet tube, a dropping funnel, and a thermometer, 80 parts by mass of propylene glycol monomethyl ether acetate and 80 parts by mass of ethyl lactate were placed, these were stirred at 80° C. while introducing nitrogen gas, and a reaction liquid was formed. A mixed liquid including 22 parts by mass of methacrylic acid, 34 parts by mass of 2-hydroxyethyl methacrylate, 42 parts by mass of methyl methacrylate, 102 parts by mass of butyl acrylate, 3 parts by mass of 2,2′-azobis(isobutyronitrile), 44 parts by mass of propylene glycol monomethyl ether acetate, and 44 parts by mass of ethyl lactate was added dropwise to the reaction liquid over 3 hours. After the dropping, the reaction liquid was stirred at 80° C. for 4 hours, and subsequently stirred at 100° C. for 2 hours. The reaction liquid was cooled to room temperature to obtain a solution of an acrylic resin having a carboxy group and a hydroxyl group (concentration: 45% by mass). The weight average molecular weight (value calculated relative to polystyrene standards) of the acrylic resin was 44000.

10 parts by mass of the solution of the acrylic resin was mixed with 20 parts by mass of ethyl lactate. A mixed liquid thus formed was filtered through a filter having a pore size of 0.5 μm to obtain a coating composition for forming a protective layer.

### 2. Dicing Test

A silicon wafer (thickness: 625 mm) having a thermal oxide film as the outermost layer was prepared. The coating composition was applied on the surface of the thermal oxide film of the silicon wafer using a spin coater to form a film of the coating composition. The silicon wafer and the film of the coating composition were heated on a hot plate set at 100° C. for 2 minutes to form a protective layer having a thickness of 1 μm, which covered the entire surface on the thermal oxide film side of the silicon wafer.

A UV-curable back grinding tape (thickness: about 180 μm) was laminated on the protective layer to obtain a surface-protected laminated body composed of a silicon wafer, a protective layer, and a back grinding tape. The silicon wafer was thinned to a thickness of 100 μm by grinding the silicon wafer from the surface on the opposite side of the protective layer using a back grinding apparatus. Thereafter, the back grinding tape was irradiated with ultraviolet radiation.

A dicing tape having a polyolefin film and an adhesive layer provided thereon was prepared. The surface-protected laminated body formed of a silicon wafer, a protective layer, and a back grinding tape was fixed onto this dicing tape in a direction in which the silicon wafer was located on the dicing tape side. Next, the back grinding tape was peeled from the surface-protected laminated body to expose the protective layer. The back grinding tape could be peeled from the protective layer without adhering to the protective layer. In that state, the silicon wafer was cut together with the protective layer along a plurality of scribe lines orthogonally intersecting one another, by dicing using a dicing saw. As a result of the cutting of the silicon wafer, singulated semiconductor chips each having square-shaped principal surfaces having a size of 5 mm×5 mm were formed. A protective layer was attached to each of the singulated multiple semiconductor chips. The laminated body after dicing was observed under a microscope, and peeling of the protective layer was not observed.

### 3. Heat Resistance of Dicing Tape

The dicing tape used for dicing was heat-treated at 50° C., 60° C., 70° C., or 80° C. for 5 minutes. In the case of a heating treatment at 50° C., the dicing tape generally maintained the shape before the heating treatment. However, as a result of a heating treatment at 60° C. or 70° C., deformation of the film due to thermal shrinkage was recognized, and as a result of a heating treatment at 80° C., hardening of the base material film due to notable thermal shrinkage was recognized. From these results, it was verified that when a protective layer is formed on a semiconductor wafer fixed onto a dicing tape by a method involving a heating treatment at 60° C. or higher, the dicing tape is deformed by thermal shrinkage, and it is difficult to perform normal dicing. According to a method including preparing a surface-protected laminated body having a protective layer and a back grinding tape, thinning the semiconductor wafer, and fixing the semiconductor wafer onto a dicing tape, semiconductor chips can be manufactured stably without being affected by thermal shrinkage of the dicing tape.

### REFERENCE SIGNS LIST

1: semiconductor wafer, 3: protective layer, 5: back grinding tape, 7: dicing tape, 10: surface-protected laminated body, 20: semiconductor chip, 30: dicing saw, hv: ultraviolet radiation, S1: circuit surface, S2: back surface.

1. A method for manufacturing a semiconductor chip, the method comprising:
preparing a surface-protected laminated body having a semiconductor wafer having a circuit surface and a back surface on an opposite side thereof, a protective layer, and a back grinding tape, the protective layer being provided so as to cover the circuit surface, and the back grinding tape being laminated on a surface of the protective layer on an opposite side of the semiconductor wafer;
grinding the semiconductor wafer included in the surface-protected laminated body from the back surface side, thereby thinning the semiconductor wafer;
fixing the surface-protected laminated body having the thinned semiconductor wafer onto a dicing tape in a direction in which the semiconductor wafer is located on the dicing tape side;
peeling the back grinding tape from the surface-protected laminated body having the thinned semiconductor wafer; and
after the back grinding tape is peeled from the surface-protected laminated body, dividing the semiconductor wafer on the dicing tape together with the protective layer, thereby forming a semiconductor chip to which the divided protective layer is attached; and
removing the protective layer attached to the semiconductor chip.

2. The method according to claim 1, wherein the back grinding tape is a UV-curable back grinding tape, and
the method further includes irradiating the back grinding tape with ultraviolet radiation, after the semiconductor wafer is thinned and before the back grinding tape is peeled from the surface-protected laminated body.

3. The method according to claim 1, wherein the surface-protected laminated body is prepared by a method including:
forming a film of a coating composition for forming a protective layer on the circuit surface of the semiconductor wafer; and
heating the film to 50° C. or higher, and thereby forming the protective layer.

4. The method according to claim 1, wherein the protective layer has a thickness of 0.3 to 20.0 μm.

5. The method according to claim 1, wherein the dicing tape has a base material film containing a polyolefin, a polyvinyl chloride, or an ethylene-vinyl acetate copolymer, and an adhesive layer provided on the base material film.

6. The method according to claim 1, wherein the protective layer contains an alkali water-soluble organic resin, and
the protective layer attached to the semiconductor chip is removed by an alkaline aqueous solution.

7. The method according to claim 6, wherein the alkali water-soluble organic resin contains at least one selected from the group consisting of an acrylic resin having a carboxy group which may form a salt, a urethane compound having a carboxy group which may form a salt, a copolymer containing an acid anhydride as a monomer unit, and a polysaccharide.
